(19) United States
(12) Patent Application Publication
(10) Pub. No.: US 2026/0096095 A1
(43) Pub. Date: Apr. 2, 2026

(54) ANTI-FUSE BIT CELL WITH DUAL GATE DIELECTRICS

(71) Applicant: Intel Corporation, Santa Clara, CA (US)

(72) Inventors: Atsunori Tanaka, Beaverton, OR (US); Sarvesh H. Kulkarni, Hillsboro, OR (US); Robin Chao, Portland, OR (US); David Hong, Tigard, OR (US); Cesar Palma Aguilar, Portland, OR (US); Aditi B. Khadilkar, Hillsboro, OR (US); Saurav Nigam, Hillsboro, OR (US); Gordon S. Freeman, Hood River, OR (US); Chetana Singh, Camas, WA (US); Zhanping Chen, Hillsboro, OR (US); Anupama Bowonder, Portland, OR (US); Biswajeet Guha, Hillsboro, OR (US)

(21) Appl. No.: 18/899,695

(22) Filed: Sep. 27, 2024

(51) Int. Cl. H10B 20/25

(52) U.S. Cl. CPC H10B 20/25

(57) ABSTRACT

Techniques are provided for forming an anti-fuse bit cell having semiconductor devices with different gate dielectric thicknesses that are separated by a material structure. Example such anti-fuse bit cells may include, for instance, a memory element (e.g., a first FET) and an access device (e.g., a second FET). According to some embodiments, the memory element is formed with a thinner gate dielectric compared to the access device. A material structure is formed between the memory element and access device to improve the patterning tolerance during the formation of the different gate dielectric thicknesses. Topside or backside connections may be made to the source or drain regions of the memory element and access device to create the connections of an anti-fuse bit cell.

### BACKGROUND

As integrated circuits continue to scale downward in size, a number of challenges arise. Memory structures continue to scale smaller, but complications arise when using relatively high voltages to program some of the elements. For example, there are fabrication limitations on how small and how close together certain fuse structures can be made, which limits their usefulness. Accordingly, there remain a number of non-trivial challenges with respect to fabricating certain memory-based structures in an integrated circuit.

### BRIEF DESCRIPTION OF THE DRAWINGS

FIG. 1A is a cross-sectional view that illustrates an example portion of an integrated circuit configured with semiconductor devices having different gate dielectric thicknesses and separated by a material structure, in accordance with an embodiment of the present disclosure.

FIG. 1B is a cross-sectional view that illustrates the semiconductor devices of FIG. 1A being connected in an anti-fuse bit cell arrangement, in accordance with an embodiment of the present disclosure.

FIG. 1C illustrates a schematic of an anti-fuse circuit, in accordance with an embodiment of the present disclosure.

FIG. 2A-2P are cross-sectional views that collectively illustrate an example process for forming semiconductor devices having different gate dielectric thicknesses and separated by a material structure, in accordance with some embodiments of the present disclosure.

FIG. 3 illustrates a cross-section view of a chip package containing one or more semiconductor dies, in accordance with an embodiment of the present disclosure.

FIG. 4 is a flowchart of a fabrication process for forming semiconductor devices having different gate dielectric thicknesses and separated by a material structure, in accordance with an embodiment of the present disclosure.

FIG. 5 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein for forming an anti-fuse bit cell having semiconductor devices with different gate dielectric thicknesses that are separated by a material structure. The techniques can be used in any number of integrated circuit applications and are particularly useful with respect to logic and memory cells, such as those cells that use finFETs or gate-all-around transistors (e.g., ribbonFETs and nanowire FETs) or forksheet transistors. Example such cells may include, for instance, an anti-fuse bit cell configuration having a memory element (e.g., a first FET) and an access device (e.g., a second FET). According to some embodiments, the memory element is formed with a thinner gate dielectric compared to the access device. A conductive or insulative material structure is formed between the memory element and access device to improve the patterning tolerance during the formation of the different gate dielectric thicknesses. Topside or backside connections may be made to the source or drain regions of the memory element and access device to create the connections of an anti-fuse bit cell. Numerous variations and embodiments will be apparent in light of this disclosure.

### General Overview

As previously noted above, it can be challenging to provide effective area scaling for fuse structures. A fuse element or memory element may be arranged in series with an access device to provide a one-time programmable bit. These anti-fuse circuits may be used in several applications, such as one-time programmable or reconfigurable read-only-memory (ROM), root-of-trust implementations for memory redundancy, and for on-chip security keys. Anti-fuse circuits use a relatively large voltage (e.g., around 5 V) during a programming operation to cause dielectric breakdown of the gate of the fuse element, thus shorting across the fuse element. Requiring such large programming voltages can be problematic, as it requires thick-gate access transistors. However, forming thick-gate access transistors adjacent to thinner-gate memory elements is difficult due to alignment tolerances as transistors continue to scale smaller.

Thus, techniques are provided herein for forming an anti-fuse bit cell using a thick-gate FET for the access device and a thin-gate FET for the memory device. According to some embodiments, the FETs are separated by a material structure that can be conductive or insulative and that provides increased alignment tolerance between the two FETs when forming the different gate dielectrics. A first FET includes a first semiconductor region extending in a first direction between first and second source or drain regions, and the second FET includes a second semiconductor region extending in the first direction between third and fourth source or drain regions. According to some embodiments, a material structure extends between the second source or drain region and the third source or drain region along the first direction. The material structure may extend above the top surfaces of the second source or drain region and the third source or drain region. In some examples, the material structure has a width along the first direction between about 60 nm and about 70 nm while the total distance between the second source or drain region and the third source or drain region along the first direction is between about 125 nm and about 145 nm. According to some embodiments, the first FET has a thinner gate dielectric thickness compared to the second FET. To use the two FETs as part of an anti-fuse bit cell, each of the first source or drain region, second source or drain region, and third source or drain region are conductively connected together, according to some embodiments.

According to an embodiment, an integrated circuit includes a first semiconductor device having a first semiconductor region extending in a first direction from a first source or drain region and a first gate structure extending in a second direction over the first semiconductor region, a second semiconductor device having a second semiconductor region extending in the first direction from a second source or drain region and a second gate structure extending in the second direction over the second semiconductor region, and a material structure extending in the second direction between the first source or drain region and the second source or drain region. The material structure also extends in a third direction along a height of the first source or drain region and the second source or drain region such that a top surface of the material structure is above a topmost surface of the first source or drain region and the second source or drain region. The first gate structure has a first gate dielectric with a first thickness, and the second gate structure has a second gate dielectric with a second thickness greater than the first thickness.

According to an embodiment, an electronic device includes a chip package having one or more dies. At least one of the one or more dies includes a first semiconductor region extending in a first direction from a first source or drain region and a first gate structure extending in a second direction over the first semiconductor region, a second semiconductor device having a second semiconductor region extending in the first direction from a second source or drain region and a second gate structure extending in the second direction over the second semiconductor region, spacer structures on the sidewalls of the first gate structure and the second gate structure and extending along the second direction with the first gate structure and the second gate structure, and a material structure extending in the second direction between the first source or drain region and the second source or drain region. The material structure extends in a third direction along a height of the first source or drain region and the second source or drain region such that a top surface of the material structure is substantially coplanar with a top surface of the spacer structures. The first gate structure has a first gate dielectric with a first thickness, and the second gate structure has a second gate dielectric with a second thickness greater than the first thickness.

According to another embodiment, an integrated circuit includes a first semiconductor device having a first semiconductor region extending in a first direction from a first source or drain region to a second source or drain region and a first gate structure extending in a second direction over the first semiconductor region, a second semiconductor device having a second semiconductor region extending in the first direction from a third source or drain region to a fourth source or drain region and a second gate structure extending in the second direction over the second semiconductor region, a material structure extending in the second direction between the second source or drain region and the third source or drain region, and one or more conductive structures that contact each of the first, second, and third source or drain regions to provide a conductive connection between each of the first, second, and third source or drain regions. The material structure extends in a third direction along a height of the second source or drain region and the third source or drain region such that a top surface of the material structure is above a topmost surface of the second source or drain region and the third source or drain region.

According to another embodiment, a method of forming an integrated circuit includes forming first, second, and third fins each comprising semiconductor material, the first, second, and third fins extending above a substrate and each extending in line with one another along a first direction such that the second fin is between the first and third fins; forming source or drain regions at the ends of each of the first, second, and third fins; removing at least a portion of the second fin between a source or drain region of the first fin and a source or drain region of the third fin to form a cavity between the first and third fins; forming a material structure within the cavity; forming a first gate dielectric with a first thickness around the semiconductor material of the first fin; forming a second gate dielectric with a second thickness less than the first thickness around the semiconductor material of the third fin; forming a first gate electrode on the first gate dielectric; and forming a second gate electrode on the second gate dielectric.

The techniques can be used with any type of planar and non-planar transistors, including finFETs (sometimes called double-gate transistors, or tri-gate transistors), nanowire and nanoribbon transistors (sometimes called gate-all-around transistors), forksheet transistors, and thin film transistors, to name a few examples. The source and drain regions can be, for example, epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a remove metal gate, or RMG, process). Any number of semiconductor materials can be used in forming the transistors to which power is being supplied by a buried or backside power rail, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of a material structure extending between adjacent FET devices having different gate dielectric thicknesses. In some embodiments, the adjacent FET devices will have their source or drain regions connected in an anti-fuse bit cell configuration. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer.

### Architecture

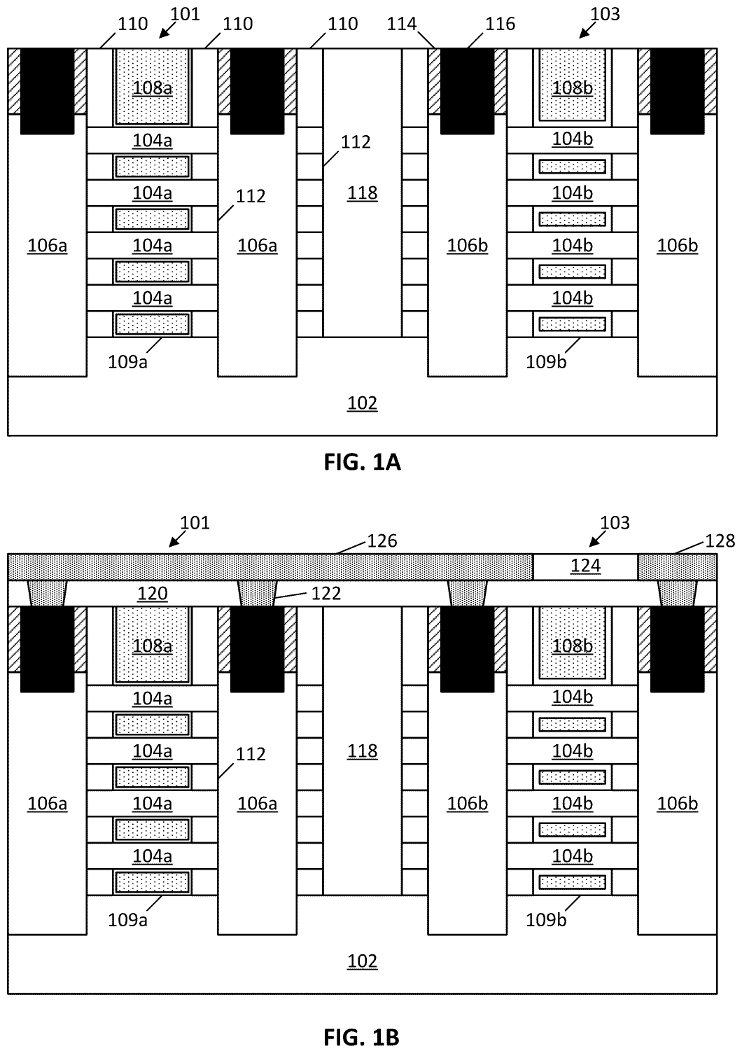

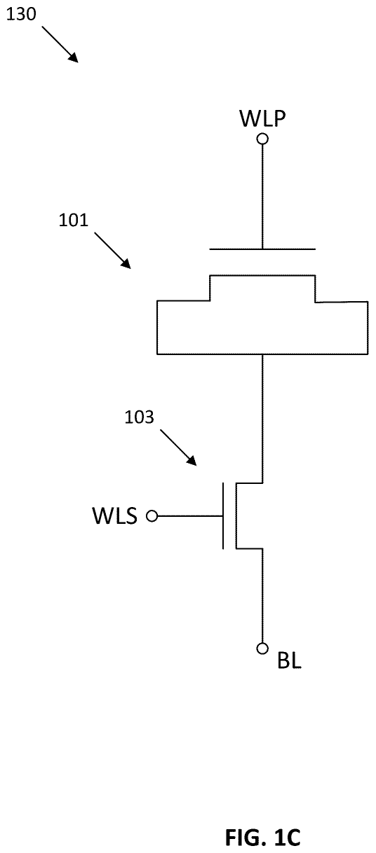

FIG. 1A is a cross-section view taken through semiconductor devices 101 and 103 along a ‘fin’ direction that illustrates the semiconductor bodies extending between source or drain regions of each of the semiconductor devices, in accordance with an embodiment of the present disclosure. FIG. 1B illustrates a cross-section view taken through the same semiconductor devices 101 and 103 having conductive interconnects to connect the devices together as part of an anti-fuse bit cell. Each of semiconductor devices 101 and 103 may be, for instance, non-planar metal oxide semiconductor (MOS) transistors, such as tri-gate (e.g., finFET), gate-all-around (GAA) transistors, or forksheet transistors although other transistor topologies and types could also benefit from the techniques provided herein. The examples herein illustrate semiconductor devices with a GAA structure (e.g., having nanoribbons, nanowires, or nanosheets that extend between source and drain regions). Other examples may have a forksheet structure having a p-type device and an n-type device separated by a dielectric spine or structure. According to some embodiments, semiconductor devices 101 and 103 are both n-channel devices (e.g., NMOS).

The semiconductor material used in each of the semiconductor devices may be formed from or on a semiconductor substrate 102. Substrate 102 can be, for example, a bulk substrate including group IV semiconductor material (such as silicon, germanium, or SiGe), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used. According to some embodiments, substrate 102 is removed following the completion of all topside processing and is replaced with a base dielectric structure.

The one or more semiconductor regions of the devices may include fins that can be, for example, native to substrate 102 (formed from the substrate itself), such as silicon fins etched from a bulk silicon substrate. Alternatively, the fins can be formed of material deposited onto the substrate. In one such example case, a blanket layer of SiGe can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons and nanosheets during a gate forming process where one type of the alternating layers is selectively etched away so as to liberate the other type of alternating layers within the channel region, so that a gate-all-around process or a forksheet gate process can then be carried out. Again, the alternating layers can be blanket deposited and then etched into fins or deposited into fin-shaped trenches, in some examples.

According to some embodiments, first semiconductor device 101 includes one or more semiconductor regions (also called channel regions), such as one or more nanoribbons 104a extending between epitaxial source or drain regions 106a in the first direction. Similarly, second semiconductor device 103 includes one or more semiconductor nanoribbons 104b extending between epitaxial source or drain regions 106b in the first direction. One or more nanoribbons 104a may extend colinearly with one or more nanoribbons 104b. Any of source or drain regions 106a/106b may act as either a source region or a drain region, depending on the application and dopant profile. Any semiconductor materials suitable for source and drain regions can be used (e.g., group IV and group III-V semiconductor materials) for any of the illustrated source or drain regions 106a/106b. In any such cases, the composition and doping of source or drain regions 106a and 106b may be the same or different, depending on the polarity of the transistors. In an example, semiconductor devices 101 and 103 are n-channel devices having a high concentration of n-type dopants in the associated source or drain regions 106a/106b. Semiconductor devices 101 and 103 may alternatively both be p-channel devices having a high concentration of p-type dopants in the associated source or drain regions 106a/106b. Example p-type dopants include boron and example n-type dopants include phosphorous or arsenic. Any number of source and drain configurations and materials can be used. In some examples, p-doped source or drain regions include silicon germanium doped with boron and n-doped source or drain regions include silicon doped with phosphorous.

A first gate structure extends over nanoribbons 104a of semiconductor device 101 in a second direction (e.g., into and out of the page) to form the transistor gate of semiconductor device 101, and second gate structure extends over nanoribbons 104b of semiconductor device 103 in the second direction to form the transistor gate of semiconductor device 103. The gate structures may each include a corresponding gate electrode 108a/108b that is made up of a conductive fill and one or more metal workfunction layers, according to some embodiments. The gate structures also include a corresponding gate dielectric 109a/109b that may represent any number of dielectric layers. The conductive fill may include any sufficiently conductive material such as a metal, metal alloy, or doped polysilicon. In some examples, the conductive fill includes tungsten (W), although other metals or conductive materials may be used, such as aluminum (Al), molybdenum (Mo), ruthenium (Ru), cobalt (Co), or doped polysilicon. In some embodiments, semiconductor devices 101 and 103 are n-channel devices having gate electrodes 108a/108b with one or more workfunction layers of tungsten. Other metal workfunction layers of n-channel devices can include tantalum nitride (TaN). In some embodiments, semiconductor devices 101 and 103 are p-channel devices having gate electrodes 108a/108b with one or more workfunction layers of molybdenum nitride (MoN). Other metal workfunction layers of p-channel devices can include tantalum nitride (TaN) and titanium nitride (TiN).

The gate dielectric 109a/109b of each gate structure may include any suitable gate dielectric material(s). In some embodiments, the gate dielectric 109a/109b includes a layer of native oxide material (e.g., silicon dioxide, germanium dioxide, or SiGe oxide) on nanoribbons 104a/104b, and a layer of high-k dielectric material (e.g., hafnium oxide or aluminum oxide) on the native oxide. According to some embodiments, gate dielectric 109a is thinner than gate dielectric 109b. For example, the silicon dioxide portion of gate dielectric 109a is thinner compared to the silicon dioxide portion of gate dielectric 109b. In some examples gate dielectric 109a is at least 10%, at least 20%, at least 30%, at least 40%, at least 50%, at least 60%, or at least 70% thinner than gate dielectric 109b.

According to some embodiments, spacer structures 110 and inner spacers 112 are present along the sidewalls of the gate structures. Spacer structures 110 and inner spacers 112 may be any suitable dielectric material, such as silicon nitride, and provide separation between a given gate structure and the adjacent source or drain region 106a/106b. Inner spacers 112 may separate adjacent nanoribbons 104a/104b from one another along a third direction (e.g., a vertical direction).

According to some embodiments, a dielectric fill 114 may be present over the source or drain regions 106a/106b within the corresponding source/drain trenches of semiconductor devices 101 and 103. A top surface of dielectric fill 114 may be substantially co-planar with a top surface of spacer structures 110. Dielectric fill 114 may include any suitable dielectric material, such as silicon dioxide, in some examples.

According to some embodiments, conductive contacts 116 are provided through dielectric fill 114 and contacting a top portion of source or drain regions 106a/106b. Conductive contacts 116 can include any suitable conductive material, such as tungsten, molybdenum, ruthenium, cobalt, or other metals. Conductive contacts 116 may be formed during the same metal deposition process(es) such that they all include the same conductive material. In some examples, conductive contacts 116 extend into a portion of the underlying source or drain region 106a/106b.

According to some embodiments, semiconductor device 101 is separated from semiconductor device 103 along the first direction by a material structure 118. Material structure 118 extends in the third direction along a height of the adjacent source or drain regions 106a/106b and above a top surface of the adjacent source or drain regions 106a/106b. In some examples, a top surface of material structure 118 is substantially coplanar with a top surface of spacer structures 110. Material structure 118 may directly abut spacer structures 110 and inner spacers 112 along sides of source or drain regions 106a/106b. In some embodiments, material structure 118 is a conductive structure that includes, for example, any of tungsten, ruthenium, molybdenum, or cobalt. In some embodiments, material structure 118 is a dielectric structure that includes, for example, silicon dioxide, silicon nitride, silicon oxynitride, or silicon oxycarbonitride.

FIG. 1B illustrates the semiconductor devices 101 and 103 along with an interconnect region above the devices having a plurality of interconnect layers to provide connections to various transistor elements, according to some embodiments. In the illustrated example, a first interconnect layer includes a first dielectric layer 120 and vias 122 extending through first dielectric layer 120 to contact underlying conductive contacts 116. First dielectric layer 120 may be any suitable dielectric material, such as silicon dioxide. Vias 122 may include any suitable conductive material, such as tungsten, ruthenium, molybdenum, or cobalt. According to some embodiments, a second interconnect layer on the first interconnect layer includes a second dielectric layer 124, a first conductive trace 126, and a second conductive trace 128. Second dielectric layer 124 may be any suitable dielectric material, such as silicon dioxide. Conductive traces 126/128 may include any suitable conductive material, such as tungsten, ruthenium, molybdenum, or cobalt. In the illustrated example, first conductive trace 126 electrically couples together both source or drain regions 106a of first semiconductor device 101 and the left source or drain region 106b of second semiconductor device 103. The right source or drain region 106b of second semiconductor device 103 may be coupled to another part of the circuit.

When set up as part of an anti-fuse bit cell, first semiconductor device 101 acts as a memory device with a thin gate dielectric 109a and second semiconductor device 103 acts as an access device with a thick gate dielectric 109b. FIG. 1C illustrates an example schematic of an anti-fuse circuit 130, according to some embodiments. Anti-fuse circuit 130 includes a memory device (first semiconductor device 101) in series with an access device (second semiconductor device 103). Since the source or drain terminals are shorted together in the memory device, the only conductive path that exists through the memory device is through gate dielectric 109a following dielectric breakdown.

When a high enough potential is applied across first semiconductor device 101, by way of the word line (WLP) and bit line (BL), such as around 5.0 V, dielectric breakdown of first semiconductor device 101 occurs and effectively shorts first semiconductor device 101. This can be done during a programming operation. Any number of anti-fuse circuits can be densely arrayed to provide permanent ‘0’ or ‘1’ bits depending on the state of first semiconductor device 101. For instance, first semiconductor device 101 provides a ‘0’ in its non-shorted state, and a ‘1’ in its shorted state. In any case, the stored value can subsequently be read out, during a read operation.

In more detail, prior to being programmed, first semiconductor device 101 has capacitor-like qualities (conductive or semiconductive regions sandwiching gate dielectric 109a). A program voltage (e.g., 5.0 V) can be applied via the WLP corresponding to that bitcell, and a lower voltage can be applied to the BL (e.g., ground). During such a programming operation, second semiconductor device 103 of that bitcell is forward biased so as to allow current to flow on the corresponding WLP and through first semiconductor device 101 of that bitcell to the corresponding BL. The access device of other bitcells in the same row as the bitcell being programmed are reverse-biased by an appropriate voltage provided on their corresponding BLs. Likewise, the access device of other bitcells in the same column as the bitcell being programmed are reverse-biased by an appropriate voltage provided on their corresponding WLS. So, one bitcell can be programmed (or read) at a time. Once programmed, first semiconductor device 101 effectively acts as a resistor. During a read operation, a read voltage (e.g., something lower than the programming voltage) can be applied via the WLP and BL corresponding to that bitcell, and the resistance of first semiconductor device 101 operates in conjunction with a resistance of a readout circuit so as to provide an indication of its programmed value (either a ‘1’ or a ‘0’, as the case may be).

### Fabrication Methodology

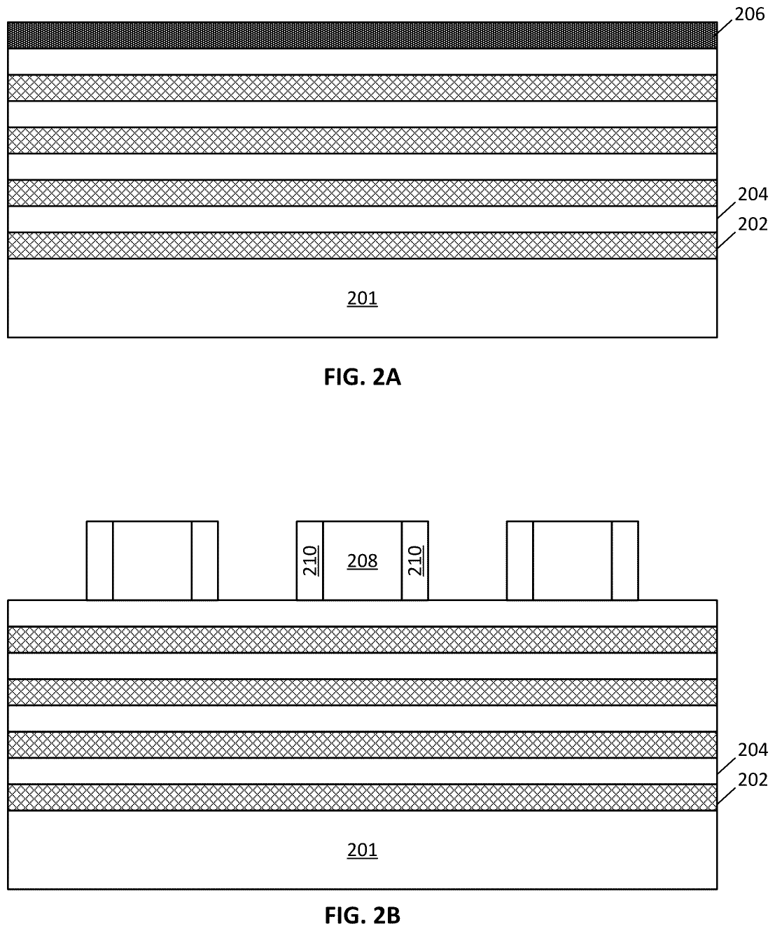

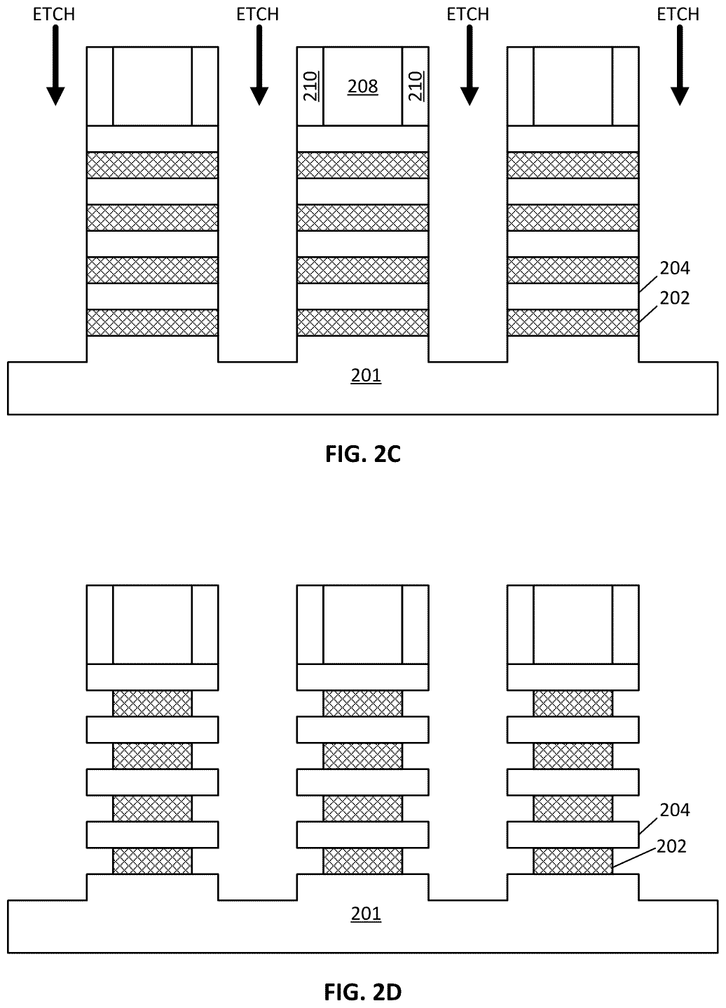

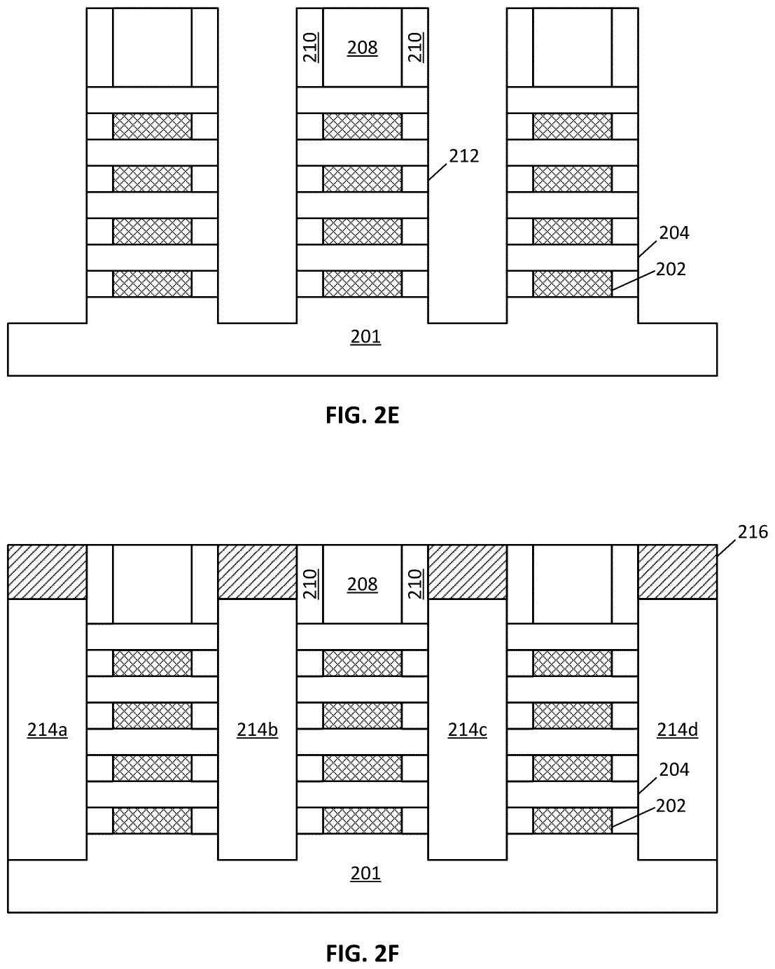

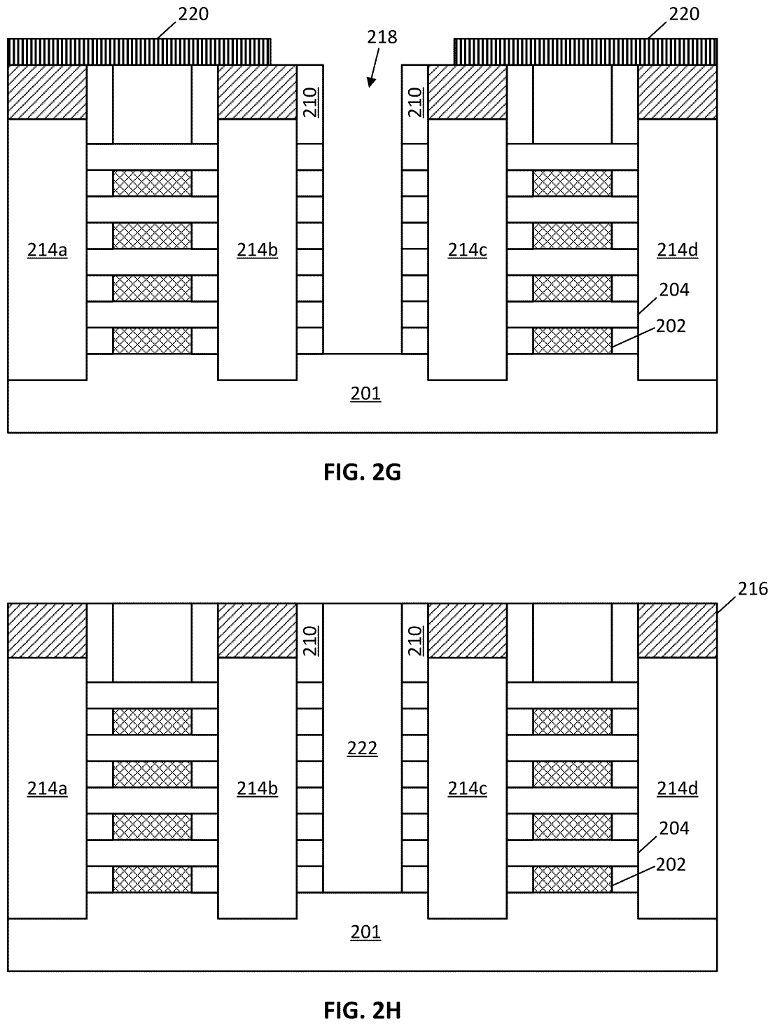

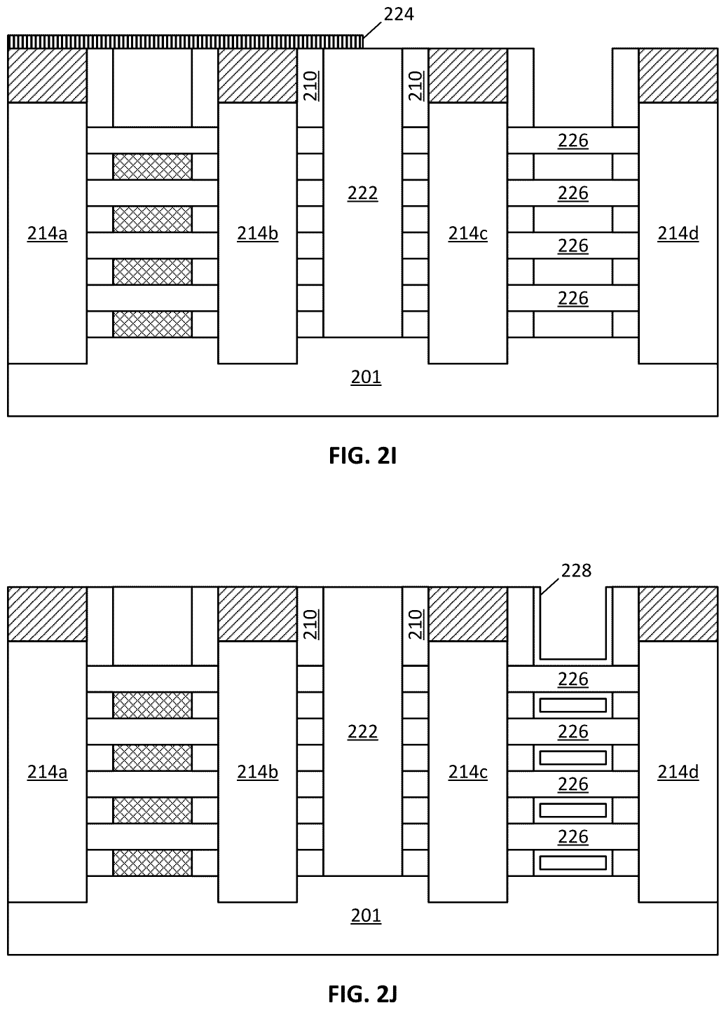

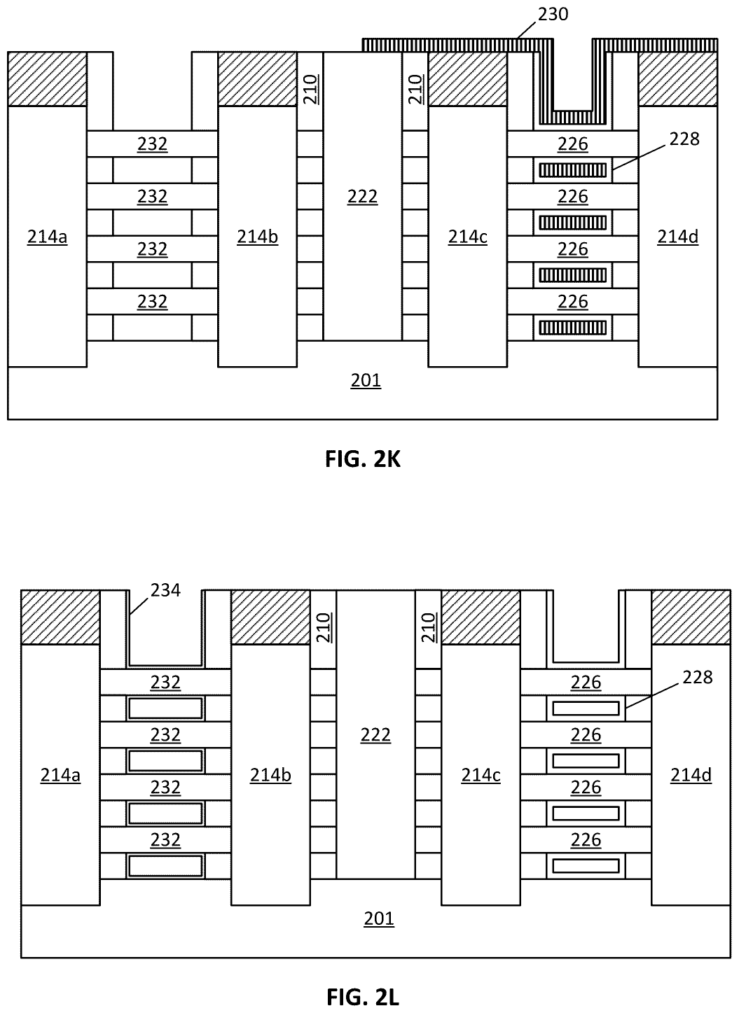

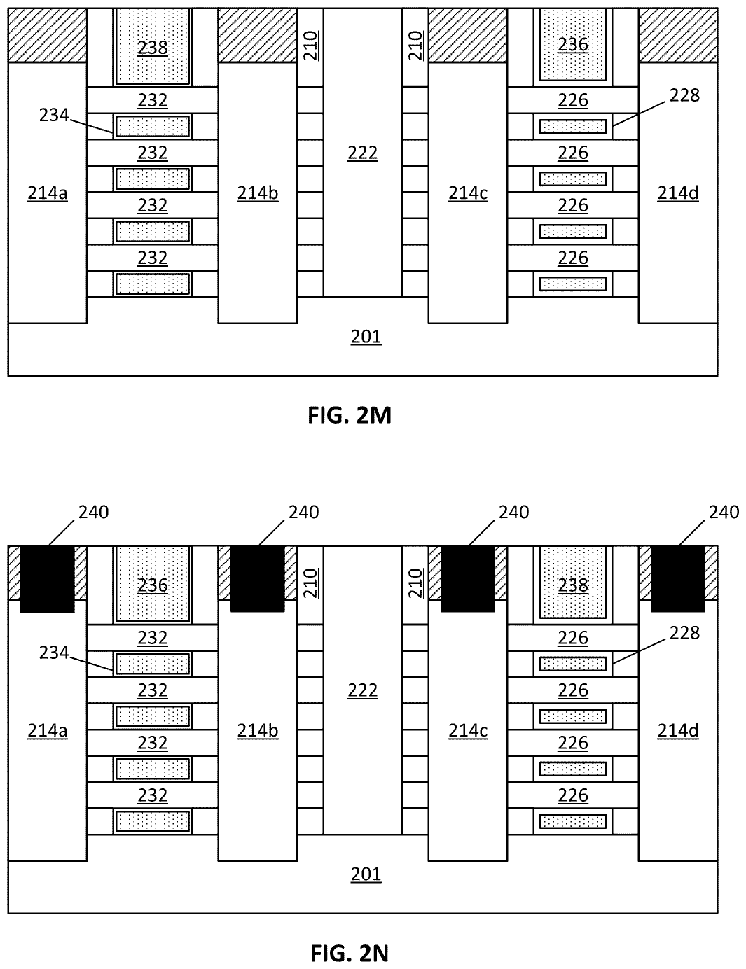

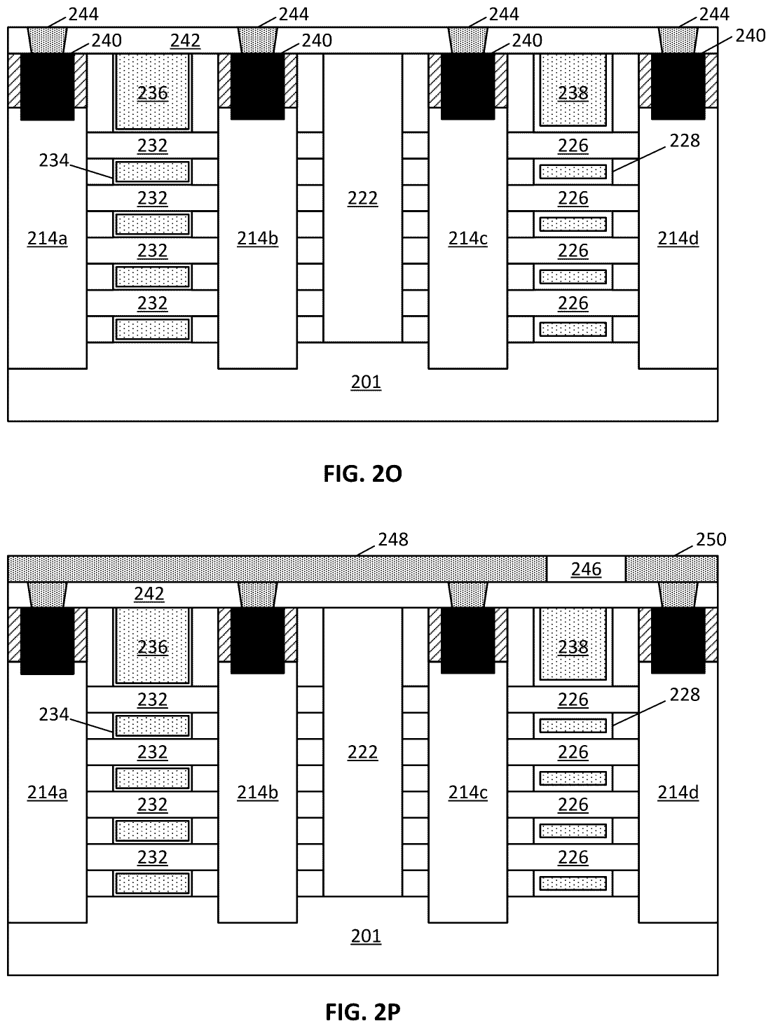

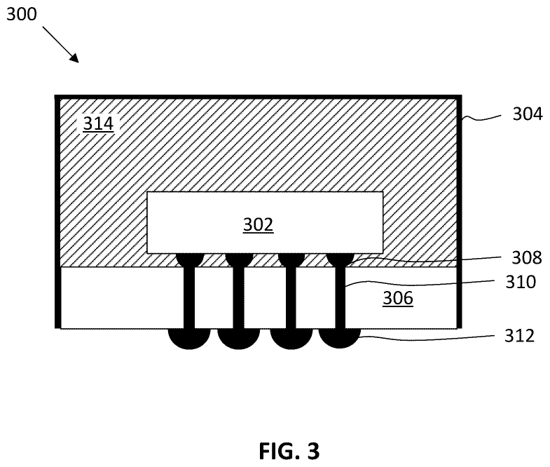

FIG. 2A-2P are cross-sectional views that collectively illustrate an example process for forming semiconductor devices of an anti-fuse bit cell, in accordance with an embodiment of the present disclosure. Each figure shows an example structure that results from the process flow up to that point in time, so the depicted structure evolves as the process flow continues, culminating in the structure shown in FIG. 2P, which is similar to the structure illustrated in FIG. 1B. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIG. 2A illustrates a cross-sectional view taken through a substrate 201 having a series of material layers formed over substrate 201, according to an embodiment of the present disclosure. Alternating material layers may be deposited over substrate 201 including sacrificial layers 202 alternating with semiconductor layers 204. The alternating layers are used to form GAA transistor structures. Any number of alternating sacrificial layers 202 and semiconductor layers 204 may be deposited over substrate 201. According to some embodiments, substrate 201 is similar to substrate 102 described above.

According to some embodiments, semiconductor layers 204 have a different material composition than sacrificial layers 202. In some embodiments, semiconductor layers 204 include a semiconductor material suitable for use as a nanoribbon such as silicon (Si), SiGe, germanium, or III-V materials like indium phosphide (InP) or gallium arsenide (GaAs). Sacrificial layers 202 include a material that can be selectively removed relative to semiconductor layers 204. In some examples, for instance, semiconductor layers 204 are silicon and sacrificial layers 202 are SiGe, or vice-versa. In some other examples where SiGe is used in each of semiconductor layers 204 and in sacrificial layers 202, the germanium concentration is different between semiconductor layers 204 and sacrificial layers 202, so as to allow for etch selectivity. For example, semiconductor layers 204 may include a higher germanium content compared to sacrificial layers 202.

While dimensions can vary from one example embodiment to the next, the thickness of each semiconductor layer 204 may be between about 5 nm and about 20 nm, in some examples. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any material deposition technique, such as chemical vapor deposition (CVD), plasma-enhanced chemical vapor deposition (PECVD), physical vapor deposition (PVD), or atomic layer deposition (ALD), or epitaxial growth.

According to some embodiments, a cap layer 206 is deposited on top of the alternating layer stack and used as a mask for patterning fins out of the alternating layer stack. Cap layer 206 may be any suitable hard mask material such as a carbon hard mask (CHM) or silicon nitride. Cap layer 206 is patterned into rows to form corresponding rows of fins from the alternating layer stack of sacrificial layers 202 and semiconductor layers 204. Cap layer 206 extends along the top of each fin in a first direction (e.g., across the page).

FIG. 2B depicts a cross-section view of the structure shown in FIG. 2A following the formation of sacrificial gates 208 and spacer structures 210, according to some embodiments. A gate masking layer may first be patterned in strips that extend orthogonally across each of the fins (e.g., in a second direction into and out of the page) in order to form corresponding sacrificial gates 208 in strips beneath the gate masking layers. Afterwards, the gate masking layers may be removed or may remain as a cap layer above each sacrificial gate 208. According to some embodiments, the sacrificial gate material is removed in all areas not protected by the gate masking layers. Sacrificial gates 208 may be any suitable material that can be selectively removed without damaging the semiconductor material of the fins. In some examples, sacrificial gates 208 includes polysilicon.

According to some embodiments, spacer structures 210 are formed along the sidewalls of sacrificial gates 208. Spacer structures 210 may be conformally deposited (e.g., CVD or ALD) and then etched back or otherwise removed (e.g., via anisotropic or directional etch) from horizontal surfaces, such that spacer structures 210 remain mostly on sidewalls of any exposed structures. The width of spacer structures 210 (along the first direction) may vary from one example to the next, but in some cases is in the range of 3 nm to 20 nm. According to some embodiments, spacer structures 210 may be any suitable dielectric material, such as silicon nitride, silicon carbon nitride, or silicon oxycarbonitride.

FIG. 2C depicts a cross-section view of the structure shown in FIG. 2B following the removal of exposed portions of the fins not protected by sacrificial gates 208 and spacer structures 210, according to some embodiments. The exposed fin portions may be removed using any anisotropic etching process, such as reactive ion etching (RIE) or other directional etch process. The removal of the exposed fin portions creates source or drain trenches that alternate with gate trenches (currently filled with sacrificial gates 208) along the first direction, according to some embodiments. In some embodiments, at least a portion of substrate 201 is also removed such that portions of the substrate adjacent to the fins are recessed below a top surface of substrate 201 directly beneath the fins. In some examples, the recessed areas may be filled with one or more dielectric materials.

FIG. 2D depicts a cross-section view of the structure shown in FIG. 2C following the removal of portions of sacrificial layers 202, according to an embodiment of the present disclosure. An isotropic etching process may be used to selectively recess the exposed ends of each sacrificial layer 202 (e.g., while etching comparatively little of semiconductor layers 204).

FIG. 2E depicts a cross-section view of the structure shown in FIG. 2D following the formation of internal spacers 212, according to an embodiment of the present disclosure. Internal spacers 212 may have a material composition that is similar to or the exact same as spacer structures 210. Accordingly, internal spacers 212 may be any suitable dielectric material that exhibits high etch selectively to semiconductor materials such as silicon and/or silicon germanium. Internal spacers 212 may be, for example, conformally deposited over the sides of the fin structure using a conformal deposition process like CVD or ALD and then etched back using an isotropic etching process to expose the ends of semiconductor layers 204. According to some embodiments, internal spacers 212 have a similar width (e.g., along the first direction) to spacer structures 210.

FIG. 2F depicts a cross-section view of the structure shown in FIG. 2E following the formation of source or drain regions 214a-214d (collectively referred to as source or drain regions 214) within the source/drain trenches, according to some embodiments. Source or drain regions 214 may be formed in the areas that had been previously occupied by the exposed fins between spacer structures 210. According to some embodiments, source or drain regions 214 are epitaxially grown from the exposed semiconductor material at the ends of semiconductor layers 204. In some example embodiments, source or drain regions 214 are p-channel source or drain regions (e.g., epitaxial silicon germanium with p-type dopants) or are n-channel source or drain regions (e.g., epitaxial silicon with n-type dopants).

According to some embodiments, a dielectric fill 216 is provided over source or drain regions 214. In some examples, dielectric fill 216 occupies a remaining volume within the source/drain trenches around and over portions of source or drain regions 214. Dielectric fill 216 may be any suitable dielectric material, such as silicon dioxide. In some examples, dielectric fill 216 extends up to and coplanar with a top surface of spacer structures 210 (e.g., following a polishing procedure).

FIG. 2G depicts a cross-section view of the structure shown in FIG. 2F following the formation of a trench recess 218 between adjacent devices, according to some embodiments. Trench recess 218 may extend along the second direction through a gate trench (e.g., through sacrificial gate 208 and the layer stack of semiconductor layers 204 and sacrificial layers 202 between spacer structures 210). Trench recess 218 may be formed by etching through the noted materials using a suitable anisotropic etching process, such as reactive ion etching (RIE). A mask structure 220 may be first formed to protect other sacrificial gates 208 during the etching procedure. In some examples, mask structure 220 is a carbon hard mask (CHM). Trench recess 218 extends along a height of the adjacent source or drain regions 214b and 214c and extends above a topmost surface of source or drain regions 214b and 214c. In some examples, trench recess 218 also extends into at least a portion of substrate 201, such as at least below a bottommost surface of source or drain regions 214b and 214c.

FIG. 2H depicts a cross-section view of the structure shown in FIG. 2G following the formation of one or more materials within trench recess 218 to form material structure 222, according to some embodiments. As noted above, material structure 222 may be an electrically conductive or electrically insulating structure. In one example, material structure 222 includes a dielectric liner deposited along all exposed surfaces of trench recess 218 followed by a dielectric fill deposited on the dielectric liner. The dielectric liner may be a high-k dielectric material, such as silicon nitride, and the dielectric fill may be a low-k dielectric material, such as silicon dioxide. In another example, material structure 222 may include a single dielectric material, such as a monolithic block of silicon dioxide, silicon nitride, silicon oxynitride, or silicon oxycarbonitride. In another example, material structure 222 includes a conductive material, such as any of tungsten, ruthenium, molybdenum, or cobalt. In any case, the top surface of material structure 222 may be polished to be substantially coplanar with a top surface of the adjacent spacer structures 210.

FIG. 2I depicts a cross-section view of the structure shown in FIG. 2H following the formation of a first mask structure 224 and removal of sacrificial gate 208 and sacrificial layers 202 from one or more exposed fins not protected by first mask structure 224, according to some embodiments. In examples where gate masking layers are still present, they may also be removed at this time. First mask structure 224 may be any suitable hard mask, such as CHM. Note that first mask structure 224 has been patterned such that it ends on the top surface of material structure 222. In this way, material structure 222 provides a wider “landing zone” for first mask structure 224 between the adjacent devices.

Once the exposed sacrificial gate 208 has been removed, the remaining fin portion within the gate trench is also exposed. In the example where the fins include alternating sacrificial layers 202 and semiconductor layers 204, sacrificial layers 202 are selectively removed to leave behind nanoribbons 226 extending along the first direction between source or drain region 214c and source or drain region 214d. It should be understood that nanoribbons 226 may also be nanowires or nanosheets. Such ribbons, wires or sheets may also be referred to as semiconductor bodies or semiconductor regions. Sacrificial gate 208 and sacrificial layers 202 may be removed using the same isotropic etching process or different isotropic etching processes.

FIG. 2J depicts a cross-section view of the structure shown in FIG. 2I following the formation of a first gate dielectric 228 over nanoribbons 226 within the exposed gate trench, and after removal of first mask structure 224, according to some embodiments. First gate dielectric 228 may be conformally deposited around nanoribbons 226 using any suitable deposition process, such as ALD. First gate dielectric 228 may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. First gate dielectric 228 may be a multilayer structure, in some examples. For instance, first gate dielectric 228 may include a first layer on nanoribbons 226, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on the gate dielectric to improve its quality when a high-k dielectric material is used. In some embodiments, first gate dielectric 228 has a first thickness. Gate dielectric 228 may also be conformally deposited or otherwise formed along the top surface of the overall structure, including along the top surfaces of 210, 216, 222, and 224. Such extraneous deposition of gate dielectric 228 can be subsequently removed along with first mask structure 224, for instance, via one or more post-deposition removal processes, such as an ashing process (e.g., to remove CHM material of first mask structure 224) and/or a chemical mechanical planarization (CMP) process to planarize the structure as shown in FIG. 2J.

In some embodiments, first gate dielectric 228 is not conformally deposited within the gate trench but rather represents thermally grown oxide (e.g., silicon dioxide or germanium oxide) on the outside surfaces of nanoribbons 226. In such examples, first gate dielectric 228 may not yet include a high-k dielectric layer at this stage of the fabrication.

FIG. 2K depicts a cross-section view of the structure shown in FIG. 2J following the removal of first mask structure 224 and the formation of second mask structure 230 over nanoribbons 226 while exposing other fins that had been previously protected by first mask structure 224, according to some embodiments. The sacrificial gate 208 and sacrificial layers 202 of those exposed other fins may also be removed using any number of isotropic etching processes to yield nanoribbons 232 extending along the first direction between source or drain region 214a and source or drain region 214b. Second mask structure 230 may be substantially similar to first mask structure 224. Note again that second mask structure 230 has been patterned such that it ends on the top surface of material structure 222.

FIG. 2L depicts a cross-section view of the structure shown in FIG. 2K following the formation of a second gate dielectric 234 over nanoribbons 232 within the exposed gate trench, according to some embodiments. Second gate dielectric 234 may be conformally deposited around nanoribbons 232 using any suitable deposition process, such as ALD. Like first gate dielectric 228, second gate dielectric 234 may include any suitable dielectric (such as silicon dioxide, and/or a high-k dielectric material). Second gate dielectric 234 may include a first layer on nanoribbons 232, and a second layer on the first layer. The first layer can be, for instance, an oxide of the semiconductor layers (e.g., silicon dioxide) and the second layer can be a high-k dielectric material (e.g., hafnium oxide). In some embodiments, second gate dielectric 234 has a second thickness that is smaller than the first thickness of first gate dielectric 228. For example, second gate dielectric 234 is at least 10%, at least 20%, at least 30%, at least 40%, at least 50%, at least 60%, or at least 70% thinner than first gate dielectric 228. In some examples, second gate dielectric 234 has a silicon dioxide layer that is thinner compared to a silicon dioxide layer of first gate dielectric 228, while both first gate dielectric 228 and second gate dielectric 234 have high-k dielectric layers that are substantially the same thickness. Similar to first gate dielectric 228, second gate dielectric 234 may also be conformally deposited or otherwise formed along the top surface of the overall structure, including along the top surfaces of 210, 216, 222, and 230. Such extraneous deposition of second gate dielectric 234 can be subsequently removed along with portions of second mask structure 230, for instance, via a CMP process to planarize the structure as shown in FIG. 2L.

In some embodiments, second gate dielectric 234 is not conformally deposited within the gate trench but rather represents thermally grown oxide (e.g., silicon dioxide or germanium oxide) on the outside surfaces of nanoribbons 232. In such examples, second gate dielectric 234 may not yet include a high-k dielectric layer at this stage of the fabrication. The grown oxide on nanoribbons 232 may be controlled such that it is thinner compared to the grown oxide on nanoribbons 226. For example, the grown oxide on nanoribbons 232 is at least 10%, at least 20%, at least 30%, at least 40%, at least 50%, at least 60%, or at least 70% thinner than the grown oxide on nanoribbons 226. In some embodiments, second mask structure 230 is removed prior to the formation of any part of second gate dielectric 234, or is removed after forming the grown oxide on nanoribbons 232.

FIG. 2M depicts a cross-section view of the structure shown in FIG. 2L following the formation of a first gate electrode 236 on first gate dielectric 228 and a second gate electrode 238 on second gate dielectric 234, according to some embodiments. Gate electrodes 236/238 may be deposited over the corresponding gate dielectric 228/234 and can be any standard or proprietary conductive material that may include any number of gate cuts. In some embodiments, the gate electrodes 236/238 include doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, one or more workfunction layers, resistance-reducing layers, and/or barrier layers. In an example, gate electrodes 236/238 include p-type workfunction materials such as, for example, titanium nitride. In an example, gate electrodes 236/238 include n-type workfunction materials such as tungsten or titanium aluminum carbide. A top surface of gate electrodes 236/238 may be polished to be substantially coplanar with a top surface of spacer structures 210.

In some embodiments, a high-k dielectric layer is conformally deposited over both the thicker thermally grown oxide on nanoribbons 226 and the thinner thermally grown oxide on nanoribbons 232 to complete the structure of first gate dielectric 228 and second gate dielectric 234. This deposition process may occur prior to the formation of first gate electrode 236 and second gate electrode 238. In some examples, a thin film of hafnium oxide is conformally deposited within both gate trenches prior to the formation of first gate dielectric 228 and second gate dielectric 234.

FIG. 2N depicts a cross-section view of the structure shown in FIG. 2M following the formation of conductive contacts 240, according to some embodiments. Conductive contacts 240 may be formed through dielectric fill 216 to contact the top surfaces of source or drain regions 214. Conductive contacts 240 may include any suitable conductive material, such as tungsten, cobalt, molybdenum, or ruthenium, for making electrical contact with the underlying source or drain regions 214.

FIG. 2O depicts a cross-section view of the structure shown in FIG. 2N following the formation of a first interconnect layer above the semiconductor devices, according to some embodiments. The first interconnect layer includes a first dielectric layer 242 and any number of vias 244 coupled to the underlying conductive contacts 240. First dielectric layer 242 may be any suitable dielectric material, such as silicon dioxide. Vias 244 may include any suitable conductive material, such as tungsten, ruthenium, molybdenum, or cobalt. Any number of other vias may also be formed through first dielectric layer 242 to contact first gate electrode 236 or second gate electrode 238 at locations into or out of the page.

FIG. 2P depicts a cross-section view of the structure shown in FIG. 2O following the formation of a second interconnect layer on the first interconnect layer, according to some embodiments. The second interconnect layer may include a second dielectric layer 246, a first conductive trace 248, and a second conductive trace 250. Second dielectric layer 246 may be any suitable dielectric material, such as silicon dioxide. Conductive traces 248/250 may include any suitable conductive material, such as tungsten, ruthenium, molybdenum, or cobalt. In the illustrated example, first conductive trace 248 electrically couples together each of source or drain regions 214a, 214b, and 214c, while second conductive trace 250 couples to source or drain region 214d. The illustrated coupling arrangement may be used to provide an anti-fuse bit cell.

FIG. 3 illustrates an example embodiment of a chip package 300, in accordance with an embodiment of the present disclosure. As can be seen, chip package 300 includes one or more dies 302. One or more dies 302 may include at least one integrated circuit having a structure as described in any of the aforementioned embodiments. One or more dies 302 may include any other circuitry used to interface with other devices formed on the dies, or other devices connected to chip package 300, in some example configurations.

As can be further seen, chip package 300 includes a housing 304 that is bonded to a package substrate 306. The housing 304 may be any standard or proprietary housing, and may provide, for example, electromagnetic shielding and environmental protection for the components of chip package 300. The one or more dies 302 may be conductively coupled to a package substrate 306 using connections 308, which may be implemented with any number of standard or proprietary connection mechanisms, such as solder bumps, ball grid array (BGA), pins, or wire bonds, to name a few examples. Package substrate 306 may be any standard or proprietary package substrate, but in some cases includes a dielectric material having conductive pathways (e.g., including conductive vias and lines) extending through the dielectric material between the faces of package substrate 306, or between different locations on each face. In some embodiments, package substrate 306 may have a thickness less than 1 millimeter (e.g., between 0.1 millimeters and 0.5 millimeters), although any number of package geometries can be used. Additional conductive contacts 312 may be disposed at an opposite face of package substrate 306 for conductively contacting, for instance, a printed circuit board (PCB). One or more vias 310 extend through a thickness of package substrate 306 to provide conductive pathways between one or more of connections 308 to one or more of contacts 312. Vias 310 are illustrated as single straight columns through package substrate 306 for ease of illustration, although other configurations can be used (e.g., damascene, dual damascene, through-silicon via, or an interconnect structure that meanders through the thickness of substrate 306 to contact one or more intermediate locations therein). In still other embodiments, vias 310 are fabricated by multiple smaller stacked vias, or are staggered at different locations across package substrate 306. In the illustrated embodiment, contacts 312 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 312, to inhibit shorting.

In some embodiments, a mold material 314 may be disposed around the one or more dies 302 included within housing 304 (e.g., between dies 302 and package substrate 306 as an underfill material, as well as between dies 302 and housing 304 as an overfill material). Although the dimensions and qualities of the mold material 314 can vary from one embodiment to the next, in some embodiments, a thickness of mold material 314 is less than 1 millimeter. Example materials that may be used for mold material 314 include epoxy mold materials, as suitable. In some cases, the mold material 314 is thermally conductive, in addition to being electrically insulating.

### Methodology

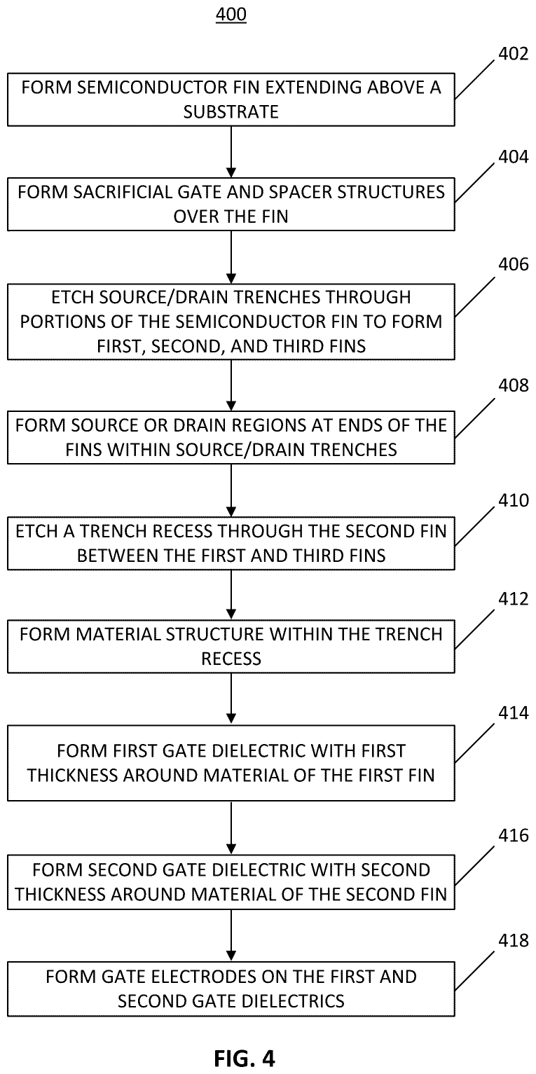

FIG. 4 is a flow chart of a method 400 for forming at least a portion of an integrated circuit, according to an embodiment. Various operations of method 400 may be illustrated in FIG. 2A-2P. However, the correlation of the various operations of method 400 to the specific components illustrated in the aforementioned figures is not intended to imply any structural and/or use limitations. Rather, the aforementioned figures provide one example embodiment of method 400. Other operations may be performed before, during, or after any of the operations of method 400. For example, method 400 does not explicitly describe various standard processes that are usually performed to form transistor structures. Some of the operations of method 400 may be performed in a different order than the illustrated order.

Method 400 begins with operation 402 where a plurality of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of SiGe can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches, according to some examples. The fins may also include a cap structure over each fin that is used to define the locations of the fins during, for example, an RIE process. The cap structure may be a dielectric material, such as silicon nitride.

According to some embodiments, a dielectric fill is formed around subfin portions of the one or more fins. In some embodiments, the dielectric fill extends between each pair of adjacent parallel fins and runs lengthwise in the same direction as the fins. In some embodiments, the anisotropic etching process that forms the fins also etches into a portion of the substrate and the dielectric fill may be formed within the recessed portions of the substrate. Accordingly, the dielectric fill acts as shallow trench isolation (STI) between adjacent fins. The dielectric fill may be any suitable dielectric material, such as silicon dioxide. Lower portions of the fins adjacent to the dielectric fill may be identified as the subfins.

Method 400 continues with operation 404 where sacrificial gates are formed over the fins. The sacrificial gates may be patterned using gate masking layers in strips that run orthogonally over the fins and parallel to one another (e.g., forming a cross-hatch pattern). The gate masking layers may be any suitable hard mask material, such as CHM or silicon nitride. The sacrificial gates themselves may be formed from any suitable material that can be selectively removed at a later time without damaging the semiconductor material of the fins. In one example, the sacrificial gates include polysilicon.

According to some embodiments, spacer structures are also formed on sidewalls of at least the sacrificial gates. The spacer structures may be deposited and then etched back such that the spacer structures remain mostly only on sidewalls of any exposed structures. In some cases, spacer structures may also be formed along sidewalls of the exposed fins running orthogonally between the strips of sacrificial gates. According to some embodiments, the spacer structures may be any suitable dielectric material, such as silicon nitride or silicon oxynitride.

Method 400 continues with operation 406 where exposed portions of the fins are removed to form source/drain trenches. Any exposed portions of the fins not covered by the sacrificial gates or spacer structures may be removed using any anisotropic etching process, such as reactive ion etching (RIE). A given fin may have multiple source/drain trenches etched through it to form at least first, second, and third smaller fins extending colinearly in a first direction. Sacrificial layers of the fins may be recessed (e.g., via isotropic etch process) followed by deposition of internal spacers (e.g., silicon nitride), as described above.

Method 400 continues with operation 408 where source or drain regions are formed at opposite ends of the first, second, and third fins within the source/drain trenches. The source or drain regions may be formed in the areas that had been previously occupied by the exposed fin portions between the spacer structures. According to some embodiments, the source or drain regions are epitaxially grown from the exposed semiconductor material of the fins (or nanoribbons, nanowires or nanosheets, as the case may be) along the exterior walls of the spacer structures. In some example embodiments, the source or drain regions are NMOS source or drain regions (e.g., epitaxial silicon with n-type dopants) or PMOS source or drain regions (e.g., epitaxial SiGe with p-type dopants). A dielectric fill may be formed between and over the source or drain regions along a given source/drain trench. The dielectric fill may be any suitable dielectric material, such as silicon dioxide. In some examples, the dielectric fill extends over the source or drain regions up to and planar with a top surface of the spacer structures. The dielectric fill also acts as an electrical insulator between adjacent source or drain regions, although some adjacent source or drain regions may have merged together during their growth.

Method 400 continues with operation 410 where a trench recess is formed through the second fin between the first and third fins. According to some embodiments, the trench recess extends along a second direction between the first and third fins to separate the semiconductor devices formed from the first and third fins. An RIE process may be used to form the trench recess through the semiconductor material of the second fin and also through the sacrificial gate material over the second fin (as the trench recess extends along the gate trench between adjacent spacer structures). Accordingly, the trench recess extends along the height of the adjacent source or drain regions.

According to some embodiments, the trench recess is etched into at least a portion the substrate such that the trench recess extends at least below a bottommost surface of the adjacent source or drain regions. In some examples, the trench recess extends below a bottom surface of the dielectric fill around the subfin portions of the fins.

Method 400 continues with operation 412 where the trench recess is filled with one or more materials to form a material structure. In one example, the material structure includes a dielectric liner deposited along all exposed surfaces of the trench recess followed by a dielectric fill deposited on the dielectric liner. The dielectric liner may be a high-k dielectric material, such as silicon nitride, and the dielectric fill may be a low-k dielectric material, such as silicon dioxide. In another example, the material structure includes a single dielectric material, such as a monolithic block of silicon dioxide, silicon nitride, silicon oxynitride, or silicon oxycarbonitride. In another example, the material structure includes a conductive material, such as any of tungsten, ruthenium, molybdenum, or cobalt. In any case, the top surface of the material structure may be polished to be substantially coplanar with a top surface of the adjacent spacer structures. Any of the materials used to form the material structure may be deposited using any of CVD, PECVD, ALD, or PVD.

Method 400 continues with operation 414 where a first gate dielectric having a first thickness is formed around the semiconductor material of the first fin. A mask structure may be used to protect the third fin while the sacrificial gate and sacrificial layers of the first fin are removed using, for example, any number of isotropic etching processes. An edge of the mask structure is directly above the material structure, according to some embodiments. The removal of the sacrificial layers yields nanoribbons (or nanowires or nanosheets) within the gate trench. The first gate dielectric may be conformally deposited around the nanoribbons using any suitable deposition process, such as ALD. The first gate dielectric may include any suitable dielectric (such as silicon dioxide, and/or a high-k dielectric material). In some examples, the first gate dielectric includes a first layer on the nanoribbons, and a second layer on the first layer. The first layer can be, for instance, an oxide of the nanoribbons (e.g., silicon dioxide) and the second layer can be a high-k dielectric material (e.g., hafnium oxide).

Method 400 continues with operation 416 where a second gate dielectric having a second thickness is formed around the semiconductor material of the third fin. Another mask structure may be used to protect the nanoribbons of the first fin while the sacrificial gate and sacrificial layers of the third fin are removed using, for example, any number of isotropic etching processes. An edge of the mask structure is directly above the material structure, according to some embodiments. The removal of the sacrificial layers yields nanoribbons (or nanowires or nanosheets) within the gate trench. The second gate dielectric may be conformally deposited around the nanoribbons of the third fin using any suitable deposition process, such as ALD. The second gate dielectric may include any suitable dielectric (such as silicon dioxide, and/or a high-k dielectric material). In some examples, the second gate dielectric includes a first layer on the nanoribbons, and a second layer on the first layer. The first layer can be, for instance, an oxide of the nanoribbons (e.g., silicon dioxide) and the second layer can be a high-k dielectric material (e.g., hafnium oxide). As noted above the second gate dielectric has a second thickness that is different than the first thickness. Accordingly, the second gate dielectric may be thicker or thinner compared to the first gate dielectric. According to some embodiments, the device having the thicker gate dielectric may be used as an access device while the device having the thinner gate dielectric may be used as a memory device within an anti-fuse bit cell.

Method 400 continues with operation 418 where gate electrodes are formed on the first and second gate dielectrics within the respective gate trenches. The gate electrodes may be deposited over the corresponding thin and thick gate dielectrics and can be any standard or proprietary conductive material that may include any number of gate cuts. In some embodiments, the gate electrodes include doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrodes may include, for instance, one or more workfunction layers, resistance-reducing layers, and/or barrier layers. In an example, the gate electrodes include p-type workfunction materials such as, for example, titanium nitride. In an example, the gate electrodes include n-type workfunction materials such as tungsten or titanium aluminum carbide. A top surface of the gate electrodes may be polished to be substantially coplanar with a top surface of the spacer structures. The gate electrode material may be deposited using any suitable technique, such as electroplating, electroless planting, CVD, PVD, or PECVD.

### Example System

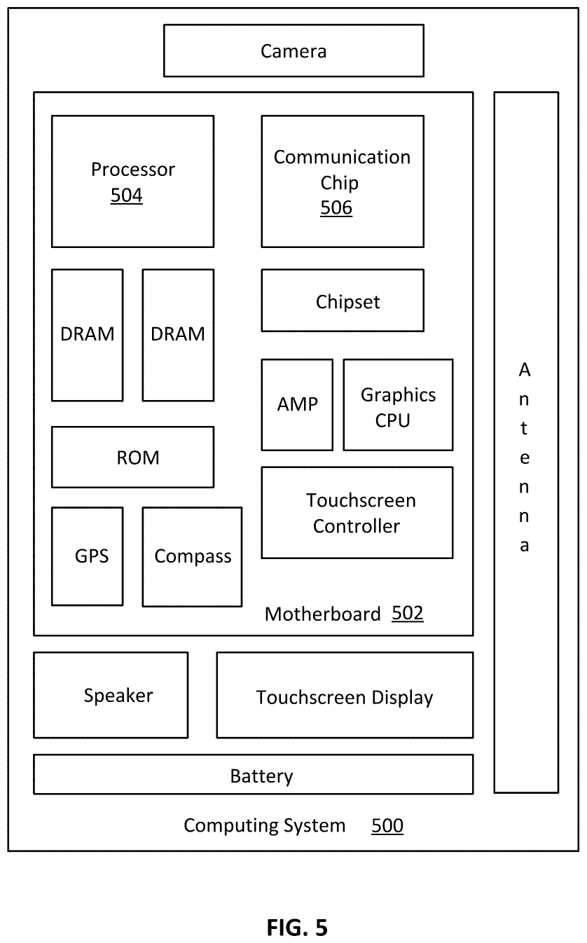

FIG. 5 is an example computing system implemented with one or more of the integrated circuit structures as disclosed herein, in accordance with some embodiments of the present disclosure. As can be seen, the computing system 500 houses a motherboard 502. The motherboard 502 may include a number of components, including, but not limited to, a processor 504 and at least one communication chip 506, each of which can be physically and electrically coupled to the motherboard 502, or otherwise integrated therein. As will be appreciated, the motherboard 502 may be, for example, any printed circuit board (PCB), whether a main board, a daughterboard mounted on a main board, or the only board of system 500, etc.

Depending on its applications, computing system 500 may include one or more other components that may or may not be physically and electrically coupled to the motherboard 502. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 500 may include one or more integrated circuit structures or devices configured in accordance with an example embodiment (e.g., a module including an integrated circuit having an anti-fuse bit cell such as any of the embodiments disclosed herein). In some embodiments, multiple functions can be integrated into one or more chips (e.g., for instance, note that the communication chip 506 can be part of or otherwise integrated into the processor 504).

The communication chip 506 enables wireless communications for the transfer of data to and from the computing system 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing system 500 includes an integrated circuit die packaged within the processor 504. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 506 also may include an integrated circuit die packaged within the communication chip 506. In accordance with some such example embodiments, the integrated circuit die of the communication chip includes one or more semiconductor devices as variously described herein. As will be appreciated in light of this disclosure, note that multi-standard wireless capability may be integrated directly into the processor 504 (e.g., where functionality of any chips 506 is integrated into processor 504, rather than having separate communication chips). Further note that processor 504 may be a chip set having such wireless capability. In short, any number of processor 504 and/or communication chips 506 can be used. Likewise, any one chip or chip set can have multiple functions integrated therein.

In various implementations, the computing system 500 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 500 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a first semiconductor device having a first semiconductor region extending in a first direction from a first source or drain region and a first gate structure extending in a second direction over the first semiconductor region, a second semiconductor device having a second semiconductor region extending in the first direction from a second source or drain region and a second gate structure extending in the second direction over the second semiconductor region, and a material structure extending in the second direction between the first source or drain region and the second source or drain region. The material structure also extends in a third direction along a height of the first source or drain region and the second source or drain region such that a top surface of the material structure is above a topmost surface of the first source or drain region and the second source or drain region. The first gate structure has a first gate dielectric with a first thickness, and the second gate structure has a second gate dielectric with a second thickness greater than the first thickness.

Example 2 includes the integrated circuit of Example 1, wherein the material structure comprises a dielectric material.

Example 3 includes the integrated circuit of Example 2, wherein the material structure comprises a dielectric liner and a dielectric fill on the dielectric liner.

Example 4 includes the integrated circuit of Example 3, wherein the dielectric liner comprises silicon and nitrogen and the dielectric fill comprises silicon and oxygen.

Example 5 includes the integrated circuit of Example 1, wherein the material structure comprises a conductive material.

Example 6 includes the integrated circuit of any one of Examples 1-5, wherein the first source or drain region is conductively coupled to the second source or drain region.

Example 7 includes the integrated circuit of Example 6, wherein the first semiconductor region extends in the first direction from the first source or drain region to a third source or drain region, and wherein the third source or drain region is conductively coupled to the first source or drain region and the second source or drain region.

Example 8 includes the integrated circuit of any one of Examples 1-7, wherein the material structure has a width along the first direction between about 60 nm and about 70 nm.

Example 9 includes the integrated circuit of any one of Examples 1-8, wherein a distance along the first direction between the first semiconductor region and the second semiconductor region is between about 125 nm and about 145 nm.

Example 10 includes the integrated circuit of any one of Examples 1-9, further comprising spacer structures on sidewalls of the first gate structure and the second gate structure and extending along the second direction with the first gate structure and the second gate structure.

Example 11 includes the integrated circuit of Example 10, wherein the top surface of the material structure is substantially coplanar with a top surface of the spacer structures.

Example 12 includes the integrated circuit of any one of Examples 1-11, wherein the first semiconductor region comprises a plurality of first semiconductor nanoribbons and the second semiconductor region comprises a plurality of second semiconductor nanoribbons.

Example 13 includes the integrated circuit of Example 12, wherein the plurality of first semiconductor nanoribbons and the plurality of second semiconductor nanoribbons comprise germanium, silicon, or a combination thereof.

Example 14 is a die that includes the integrated circuit of any one of Examples 1-13.

Example 15 is an electronic device that includes a chip package having one or more dies. At least one of the one or more dies includes a first semiconductor region extending in a first direction from a first source or drain region and a first gate structure extending in a second direction over the first semiconductor region, a second semiconductor device having a second semiconductor region extending in the first direction from a second source or drain region and a second gate structure extending in the second direction over the second semiconductor region, spacer structures on the sidewalls of the first gate structure and the second gate structure and extending along the second direction with the first gate structure and the second gate structure, and a material structure extending in the second direction between the first source or drain region and the second source or drain region. The material structure extends in a third direction along a height of the first source or drain region and the second source or drain region such that a top surface of the material structure is substantially coplanar with a top surface of the spacer structures. The first gate structure has a first gate dielectric with a first thickness, and the second gate structure has a second gate dielectric with a second thickness greater than the first thickness.

Example 16 includes the electronic device of Example 15, wherein the material structure comprises a dielectric material.

Example 17 includes the electronic device of Example 16, wherein the material structure comprises a dielectric liner and a dielectric fill on the dielectric liner.

Example 18 includes the electronic device of Example 17, wherein the dielectric liner comprises silicon and nitrogen and the dielectric fill comprises silicon and oxygen.

Example 19 includes the electronic device of Example 15, wherein the material structure comprises a conductive material.

Example 20 includes the electronic device of any one of Examples 15-19, wherein the first source or drain region is conductively coupled to the second source or drain region.

Example 21 includes the electronic device of Example 20, wherein the first semiconductor region extends in the first direction from the first source or drain region to a third source or drain region, and wherein the third source or drain region is conductively coupled to the first source or drain region and the second source or drain region.

Example 22 includes the electronic device of any one of Examples 15-21, wherein the material structure has a width along the first direction between about 60 nm and about 70 nm.

Example 23 includes the electronic device of any one of Examples 15-22, wherein a distance along the first direction between the first semiconductor region and the second semiconductor region is between about 125 nm and about 145 nm.

Example 24 includes the electronic device of any one of Examples 15-23, wherein the first semiconductor region comprises a plurality of first semiconductor nanoribbons and the second semiconductor region comprises a plurality of second semiconductor nanoribbons.

Example 25 includes the electronic device of Example 24, wherein the plurality of first semiconductor nanoribbons and the plurality of second semiconductor nanoribbons comprise germanium, silicon, or a combination thereof.

Example 26 includes the electronic device of any one of Examples 15-25, further comprising a printed circuit board, wherein the chip package is coupled to the printed circuit board.

Example 27 is a method of forming an integrated circuit. The method includes forming first, second, and third fins each comprising semiconductor material, the first, second, and third fins extending above a substrate and each extending in line with one another along a first direction such that the second fin is between the first and third fins; forming source or drain regions at the ends of each of the first, second, and third fins; removing at least a portion of the second fin between a source or drain region of the first fin and a source or drain region of the third fin to form a cavity between the first and third fins; forming a material structure within the cavity; forming a first gate dielectric with a first thickness around the semiconductor material of the first fin; forming a second gate dielectric with a second thickness less than the first thickness around the semiconductor material of the third fin; forming a first gate electrode on the first gate dielectric; and forming a second gate electrode on the second gate dielectric.

Example 28 includes the method of Example 27, wherein forming the material structure comprises forming a dielectric structure.

Example 29 includes the method of Example 27, wherein forming the material structure comprises forming a conductive structure.

Example 30 includes the method of any one of Examples 27-29, further comprising forming one or more conductive interconnect structures that contact both the source or drain region of the first fin and the source or drain region of the third fin.

Example 31 is an integrated circuit that includes a first semiconductor device having a first semiconductor region extending in a first direction from a first source or drain region to a second source or drain region and a first gate structure extending in a second direction over the first semiconductor region, a second semiconductor device having a second semiconductor region extending in the first direction from a third source or drain region to a fourth source or drain region and a second gate structure extending in the second direction over the second semiconductor region, a material structure extending in the second direction between the second source or drain region and the third source or drain region, and one or more conductive structures that contact each of the first, second, and third source or drain regions to provide a conductive connection between each of the first, second, and third source or drain regions. The material structure extends in a third direction along a height of the second source or drain region and the third source or drain region such that a top surface of the material structure is above a topmost surface of the second source or drain region and the third source or drain region.

Example 32 includes the integrated circuit of Example 31, wherein the material structure comprises a dielectric material.

Example 33 includes the integrated circuit of Example 32, wherein the material structure comprises a dielectric liner and a dielectric fill on the dielectric liner.

Example 34 includes the integrated circuit of Example 33, wherein the dielectric liner comprises silicon and nitrogen and the dielectric fill comprises silicon and oxygen.

Example 35 includes the integrated circuit of Example 31, wherein the material structure comprises a conductive material.

Example 36 includes the integrated circuit of any one of Examples 31-35, wherein the first gate structure has a first gate dielectric with a first thickness and the second gate structure has a second gate dielectric with a second thickness greater than the first thickness.

Example 37 includes the integrated circuit of any one of Examples 31-36, wherein the material structure has a width along the first direction between about 60 nm and about 70 nm.

Example 38 includes the integrated circuit of any one of Examples 31-37, wherein a distance along the first direction between the first semiconductor region and the second semiconductor region is between about 125 nm and about 145 nm.

Example 39 includes the integrated circuit of any one of Examples 31-38, further comprising spacer structures on sidewalls of the first gate structure and the second gate structure and extending along the second direction with the first gate structure and the second gate structure.

Example 40 includes the integrated circuit of Example 39, wherein the top surface of the material structure is substantially coplanar with a top surface of the spacer structures.

Example 41 includes the integrated circuit of any one of Examples 31-40, wherein the first semiconductor region comprises a plurality of first semiconductor nanoribbons and the second semiconductor region comprises a plurality of second semiconductor nanoribbons.

Example 42 includes the integrated circuit of Example 41, wherein the plurality of first semiconductor nanoribbons and the plurality of second semiconductor nanoribbons comprise germanium, silicon, or a combination thereof.

Example 43 is a die that includes the integrated circuit of any one of Examples 31-42.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having a first semiconductor region extending in a first direction from a first source or drain region, and a first gate structure extending in a second direction over the first semiconductor region;
a second semiconductor device having a second semiconductor region extending in the first direction from a second source or drain region, and a second gate structure extending in the second direction over the second semiconductor region; and
a material structure extending in the second direction between the first source or drain region and the second source or drain region, and extending in a third direction along a height of the first source or drain region and the second source or drain region such that a top surface of the material structure is above a topmost surface of the first source or drain region and the second source or drain region,
wherein the first gate structure has a first gate dielectric with a first thickness, and the second gate structure has a second gate dielectric with a second thickness greater than the first thickness.

2. The integrated circuit of claim 1, wherein the material structure comprises a dielectric material.

3. The integrated circuit of claim 1, wherein the material structure comprises a conductive material.

4. The integrated circuit of claim 1, wherein the first source or drain region is conductively coupled to the second source or drain region.

5. The integrated circuit of claim 4, wherein the first semiconductor region extends in the first direction from the first source or drain region to a third source or drain region, and wherein the third source or drain region is conductively coupled to the first source or drain region and the second source or drain region.

6. The integrated circuit of claim 1, wherein the material structure has a width along the first direction between about 60 nm and about 70 nm.

7. The integrated circuit of claim 1, further comprising spacer structures on sidewalls of the first gate structure and the second gate structure and extending along the second direction with the first gate structure and the second gate structure.

8. The integrated circuit of claim 7, wherein the top surface of the material structure is substantially coplanar with a top surface of the spacer structures.

9. A die comprising the integrated circuit of claim 1.

10. An electronic device, comprising:
a chip package comprising one or more dies, at least one of the one or more dies comprising
a first semiconductor device having a first semiconductor region extending in a first direction from a first source or drain region, and a first gate structure extending in a second direction over the first semiconductor region;
a second semiconductor device having a second semiconductor region extending in the first direction from a second source or drain region, and a second gate structure extending in the second direction over the second semiconductor region;
spacer structures on sidewalls of the first gate structure and the second gate structure and extending along the second direction with the first gate structure and the second gate structure; and
a material structure extending in the second direction between the first source or drain region and the second source or drain region, and extending in a third direction along a height of the first source or drain region and the second source or drain region such that a top surface of the material structure is substantially coplanar with a top surface of the spacer structures,
wherein the first gate structure has a first gate dielectric with a first thickness, and the second gate structure has a second gate dielectric with a second thickness greater than the first thickness.

11. The electronic device of claim 10, wherein the material structure comprises a dielectric material.

12. The electronic device of claim 10, wherein the material structure comprises a conductive material.

13. The electronic device of claim 10, wherein the first source or drain region is conductively coupled to the second source or drain region.

14. The electronic device of claim 13, wherein the first semiconductor region extends in the first direction from the first source or drain region to a third source or drain region, and wherein the third source or drain region is conductively coupled to the first source or drain region and the second source or drain region.

15. An integrated circuit comprising:
a first semiconductor device having a first semiconductor region extending in a first direction from a first source or drain region to a second source or drain region, and a first gate structure extending in a second direction over the first semiconductor region;
a second semiconductor device having a second semiconductor region extending in the first direction from a third source or drain region to a fourth source or drain region, and a second gate structure extending in the second direction over the second semiconductor region;
a material structure extending in the second direction between the second source or drain region and the third source or drain region, and extending in a third direction along a height of the second source or drain region and the third source or drain region such that a top surface of the material structure is above a topmost surface of the second source or drain region and the third source or drain region; and
one or more conductive structures that contact each of the first, second, and third source or drain regions to provide a conductive connection between each of the first, second, and third source or drain regions.

16. The integrated circuit of claim 15, wherein the first gate structure has a first gate dielectric with a first thickness and the second gate structure has a second gate dielectric with a second thickness greater than the first thickness.

17. The integrated circuit of claim 15, wherein the material structure has a width along the first direction between about 60 nm and about 70 nm.

18. The integrated circuit of claim 15, wherein a distance along the first direction between the first semiconductor region and the second semiconductor region is between about 125 nm and about 145 nm.

19. The integrated circuit of claim 15, further comprising spacer structures on sidewalls of the first gate structure and the second gate structure and extending along the second direction with the first gate structure and the second gate structure.

20. The integrated circuit of claim 19, wherein the top surface of the material structure is substantially coplanar with a top surface of the spacer structures.
